(19) United States
(12) Patent Application Publication
(10) Pub. No.: US 2026/0011876 A1
(43) Pub. Date: Jan. 8, 2026

(54) BUSBAR TERMINAL BLOCK, MANAGEMENT UNIT, AND ENERGY STORAGE APPARATUS

(71) Applicant: GS Yuasa International Ltd., Kyoto-shi (JP)

(72) Inventor: Ryo UEDA, Kyoto-shi (JP)

(21) Appl. No.: 19/327,184

(22) Filed: Sep. 12, 2025

Related U.S. Application Data
(63) Continuation of application No. PCT/JP2024/007189, filed on Feb. 28, 2024.

(30) Foreign Application Priority Data
Mar. 24, 2023 (JP) 2023-047670

(51) Int. Cl. H01M 50/519; H01M 10/42; H01M 50/507; H01M 50/514; H01M 50/569; H05K 1/18

(52) U.S. Cl. CPC H01M 50/519; H01M 10/4257; H01M 50/507; H01M 50/514; H01M 50/569; H05K 1/181; H01M 2010/4271; H05K 2201/10022; H05K 2201/10272

(57) ABSTRACT

A busbar terminal block is made of a conductive material and includes a plate portion including a board contact surface, the board contact surface coming into contact with a first surface of a circuit board, and a post portion that extends from the plate portion through the circuit board and projects from a second surface of the circuit board. The plate portion includes a first support surface opposite the board contact surface. The post portion includes a second support surface at the distal end that projects from the second surface. The plate portion and the post portion include an insertion hole extending from the first support surface to the second support surface, through which a fastener is inserted.

### CROSS REFERENCE TO RELATED APPLICATIONS

This application claims the benefit of priority to Japanese Patent Application No. 2023-047670 filed on Mar. 24, 2023 and is a Continuation Application of PCT Application No. PCT/JP2024/007189 filed on Feb. 28, 2024. The entire contents of each application are hereby incorporated herein by reference.

### BACKGROUND OF THE INVENTION

### 1. Field of the Invention

The present invention relates to busbar terminal blocks, management units, and energy storage apparatuses.

### 2. Description of the Related Art

JP-A-2023-32847 discloses a resistor (shunt resistor) capable of reducing stress generated at the time of mounting or the like. A plurality of stacked resistor components includes plate portions that extend from both sides of resistance elements and are fixed to busbars with bolts and nuts. Metal rod-shaped members as a detection unit are provided at positions on the plate portions close to the resistance elements.

### SUMMARY OF THE INVENTION

A management unit in an energy storage apparatus such as an in-vehicle battery includes a circuit board and a shunt resistor for current measurement. The shunt resistor is fixed on the circuit board to improve space efficiency and manufacturability.

In the case where the rod-shaped members (current detection pins) of the shunt resistor with the integrally-formed plate portions as disclosed in JP-A-2023-32847 are directly fixed to the board, the current detection pins may be broken due to metal fatigue caused by vibration.

The present inventor has studied the use of a small and inexpensive surface mount device (SMD)-type shunt resistor mounted on a surface of a circuit board in an energy storage apparatus such as an in-vehicle battery, instead of a shunt resistor with integrally-formed plate portions. The SMD-type shunt resistor mounted on the board surface is connected to busbars that are conductive paths outside the board via wiring on the board. In order to form the power line (charge-discharge path), it is necessary to fix the busbars to the board with low contact resistance.

When the busbars are tightly fastened to the board with bolts and nuts, the board can be partially crushed, causing bolt loosening due to a creep phenomenon over time. In order to measure current accurately, it is desired to fix the busbars to the board with high reliability.

Example embodiments of the present invention provide busbar terminal blocks each configured to fix a busbar to a circuit board, and management units and energy storage apparatuses including busbar terminal blocks.

A busbar terminal block according to an example embodiment of the present invention includes a conductive material, a plate portion including a board contact surface contactable with a first surface of a circuit board, and a post portion that extends from the plate portion through the circuit board and projects from a second surface of the circuit board. The plate portion includes a first support surface opposite the board contact surface. The post portion includes a second support surface at a distal end that projects from the second surface. The plate portion and the post portion include an insertion hole through which a fastener is inserted, the insertion hole linearly extending from the first support surface to the second support surface.

According to the above example embodiment, the busbar terminal block to fix a busbar to a circuit board can be provided. The busbar terminal block with the first support surface and the second support surface allows a busbar to be fixed to either the upper side or the lower side of the board with high reliability.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a perspective view illustrating a configuration example of an energy storage apparatus.

FIG. 2 is an exploded perspective view of the energy storage apparatus.

FIG. 3 is a perspective view illustrating a first configuration example of a busbar terminal block.

FIG. 4 is a perspective view illustrating a second configuration example of a busbar terminal block.

FIG. 5 is a perspective view illustrating a third configuration example of a busbar terminal block.

FIG. 6 is a perspective view illustrating a modification example of a busbar terminal block.

FIG. 7A is a perspective view of the upper surface of a circuit board illustrating the first configuration example and the modification example mounted to the board, and FIG. 7B is a side view.

FIG. 8 is a perspective view of the lower surface of the circuit board illustrating the first configuration example and the modification example mounted to the board.

FIG. 9A is a side view illustrating a busbar fixed to the upper side of the board using the first configuration example, and FIG. 9B is a side view illustrating a busbar fixed to the lower side of the board using the first configuration example.

FIG. 10 is a side view illustrating busbars fixed to the upper side and the lower side of the board using the first configuration example.

FIG. 11 is a conceptual diagram illustrating busbars disposed on the upper side of the board and busbars disposed on the lower side of the board in the energy storage apparatus.

### DETAILED DESCRIPTION OF THE EXAMPLE EMBODIMENTS

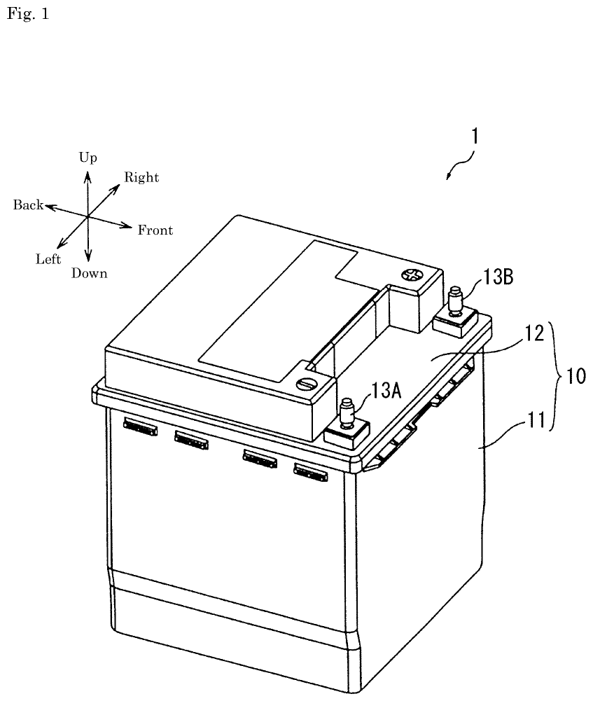

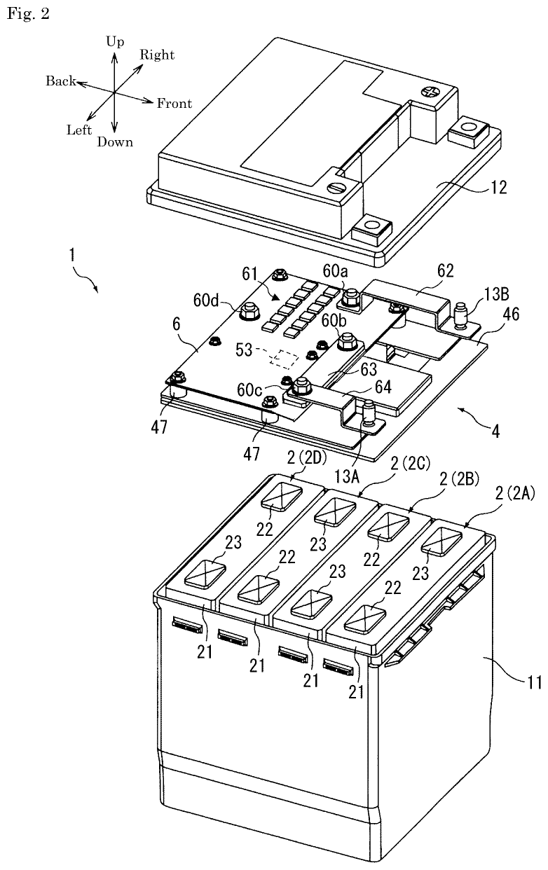

Hereinafter, specific description will be given with reference to the drawings illustrating example embodiments of the present invention. FIG. 1 is a perspective view illustrating a configuration example of an energy storage apparatus 1. FIG. 2 is an exploded perspective view of the energy storage apparatus 1. The following describes the configuration example of the energy storage apparatus 1 with reference to “front-back”, “left-right”, and “up-down” directions shown in the drawings.

The energy storage apparatus 1 is, for example, a battery suitably mounted in a vehicle such as an engine vehicle, an electric vehicle (EV), a hybrid electric vehicle (HEV), or a plug-in hybrid electric vehicle (PHEV), or another mobile object. The energy storage apparatus 1 of the present example embodiment is used in place of a lead-acid battery, and is rated at 12 volts (V). Alternatively, the energy storage apparatus may be rated at 24 V or 48 V, or may be used in stationary applications.

The energy storage apparatus 1 includes energy storage devices 2, a busbar unit 4, and a circuit board 6 (battery management unit: BMU). The energy storage devices 2, the busbar unit 4, and the circuit board 6 are housed in a housing case 10.

The housing case 10 is made of synthetic resin, and includes a case body 11 open at the top, and a cover 12 that covers the opening of the case body 11. The dimensions of the case body 11 and the cover 12 are designed according to the dimensions and the number of the energy storage devices 2 housed inside. The case body 11 and the cover 12 are liquid-tightly fixed to each other with fasteners such as screws or an adhesive or by welding or the like, with the energy storage devices 2, the busbar unit 4, and the circuit board 6 housed therein.

The energy storage devices 2 are, for example, lithium ion secondary batteries (battery cells). Each energy storage device 2 includes a case 21 having a hollow rectangular parallelepiped shape. On the upper surface (terminal surface) of the case 21, a positive terminal 22 and a negative terminal 23 of the energy storage device 2 are provided. An electrode assembly, an electrolyte solution, and the like are held in the case 21. Alternatively, the energy storage devices 2 may be battery cells such as all-solid-state batteries or nickel-metal hydride batteries, or may be capacitors.

The energy storage devices 2 are prismatic battery cells including a rolled electrode assembly. Alternatively, the energy storage devices 2 may be cylindrical battery cells or laminated (pouch) battery cells, or may be battery cells including a stacked electrode assembly.

The four energy storage devices 2 are connected in series to construct an assembled battery. Alternatively, some of the energy storage devices 2 may be connected in parallel. For example, the assembled battery may include eight energy storage devices 2 connected with four in series and two in parallel, or may include twelve energy storage devices 2 connected with four in series and three in parallel.

Hereinafter, the energy storage devices 2 are also referred to as a first energy storage device 2A, a second energy storage device 2B, a third energy storage device 2C, and a fourth energy storage device 2D from the front side of the case body 11 in this order. The second energy storage device 2B is disposed adjacent to the rear surface of the first energy storage device 2A, the third energy storage device 2C is disposed adjacent to the rear surface of the second energy storage device 2B, and the fourth energy storage device 2D is disposed adjacent to the rear surface of the third energy storage device 2C.

In the example of FIG. 2, the first energy storage device 2A and the third energy storage device 2C are housed in the case body 11 in an orientation in which the positive terminal 22 is on the left and the negative terminal 23 is on the right, and the second energy storage device 2B and the fourth energy storage device 2D are housed in the case body 11 in an orientation in which the positive terminal 22 is on the right and the negative terminal 23 is on the left.

The busbar unit 4 is disposed on the terminal surfaces of the energy storage devices 2. The busbar unit 4 includes a busbar frame 46. The circuit board 6 is disposed on the upper surface of the busbar frame 46. The circuit board 6 is fixed to the busbar frame 46 via spacers 47. Hereinafter, both the BMU in which various components are mounted on the board and the board itself are collectively referred to as the circuit board 6.

The circuit board 6 includes, on its upper surface, a circuit breaker 61 for cutting off power lines. The circuit breaker 61 may include a plurality of field-effect transistors (FETs) connected in series and parallel, or relays. From the viewpoint of miniaturization and cost reduction, it is preferable to configure the circuit breaker 61 with FETs.

The circuit board 6 includes an SMD-type shunt resistor 53 on its upper surface or lower surface. Busbars 62, 63, and 64 are fixed to the upper surface of the circuit board 6 with fasteners 60a, 60b, and 60c, using busbar terminal blocks described below. Instead of the SMD-type shunt resistor 53, a shunt resistor with integrally-formed plate portions may be disposed at a place where the busbar 63 is disposed.

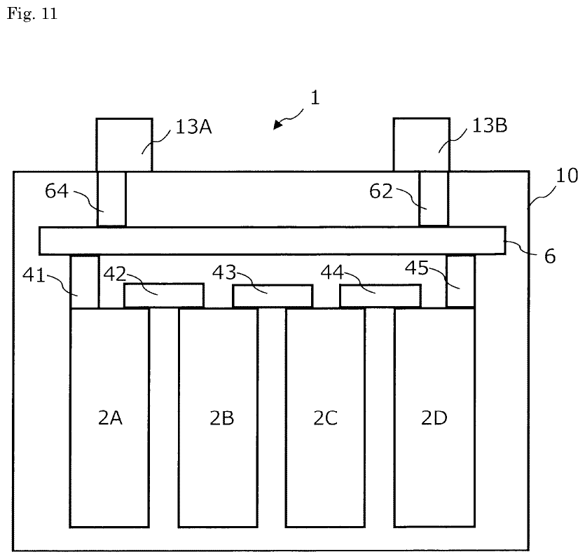

A fastener 60d secures a busbar 45 (see FIG. 11) to the lower surface of the circuit board 6, using a busbar terminal block described below.

From the viewpoint of manufacturability of the energy storage apparatus 1, the fasteners 60a to 60d are preferably bolts or screws that can be fastened (for example, rotationally operated) from the upper side.

As illustrated in FIG. 11, the in-vehicle 12 V battery using the lithium ion secondary batteries includes busbars 41 and 45 disposed on the lower side of the circuit board 6 to connect the board 6 and the energy storage devices 2, in addition to the busbars 64 and 62 disposed on the upper side of the board 6 to connect the board 6 and external terminals 13A and 13B. Busbars 42 to 44 are also disposed on the lower side of the board 6 to connect the positive terminals 22 and the negative terminals 23 of the adjacent energy storage devices 2.

These busbars are conductive paths outside the board that form power lines (charge-discharge paths) for the energy storage devices 2. The busbars are made of metal and are formed of a material having excellent conductivity and high thermal conductivity, such as aluminum, an aluminum alloy, copper, a copper alloy, or stainless steel.

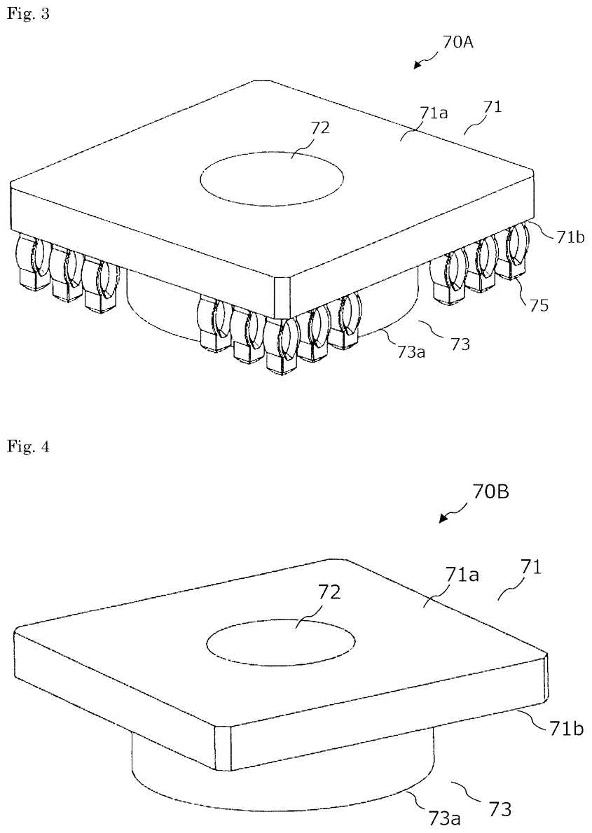

FIG. 3 illustrates a first configuration example of a busbar terminal block for fixing a busbar to the board. A busbar terminal block 70A is made of a conductive material and includes a plate portion 71 with a board contact surface 71b. The board contact surface 71b comes into surface contact with a first surface of the circuit board 6 (for example, the upper surface of the board 6 illustrated in FIG. 2). The busbar terminal block 70A includes a post portion 73 that extends from the plate portion 71 through the circuit board 6 and projects from a second surface of the circuit board 6 (for example, the lower surface of the board 6 illustrated in FIG. 2).

The plate portion 71 illustrated in FIG. 3 includes a first support surface 71a opposite the board contact surface 71b. The post portion 73 includes a second support surface 73a at its distal end that projects from the second surface of the board 6. The plate portion 71 and the post portion 73 include an insertion hole 72 linearly extending from the first support surface 71a to the second support surface 73a, through which a fastener is inserted.

The busbar terminal block 70A illustrated in FIG. 3 further includes a plurality of metal press-fit pins 75 as a fixing member around the post portion 73 on the board contact surface 71b of the plate portion 71. By press-fitting the press-fit pins 75 into the board 6, the board contact surface 71b of the plate portion 71 can be firmly fixed to the board 6. The conductive busbar terminal block 70A can be fixed to wiring on the board 6 with low contact resistance. In that state, the second support surface 73a of the post portion 73 projects from the opposite surface of the board 6.

FIG. 4 illustrates a second configuration example of a busbar terminal block. A busbar terminal block 70B is different from the example of FIG. 3 in that it does not include press-fit pins, but the other configuration is the same as that of the example of FIG. 3. The busbar terminal block 70B eliminates the need for a press-fit jig for press fitting at the time of mounting, and has good mountability. The busbar terminal block 70B allows the board contact surface 71b of the plate portion 71 to be fixed to the board 6 by reflow soldering (not illustrated). In that state, the second support surface 73a of the post portion 73 projects from the opposite surface of the board 6.

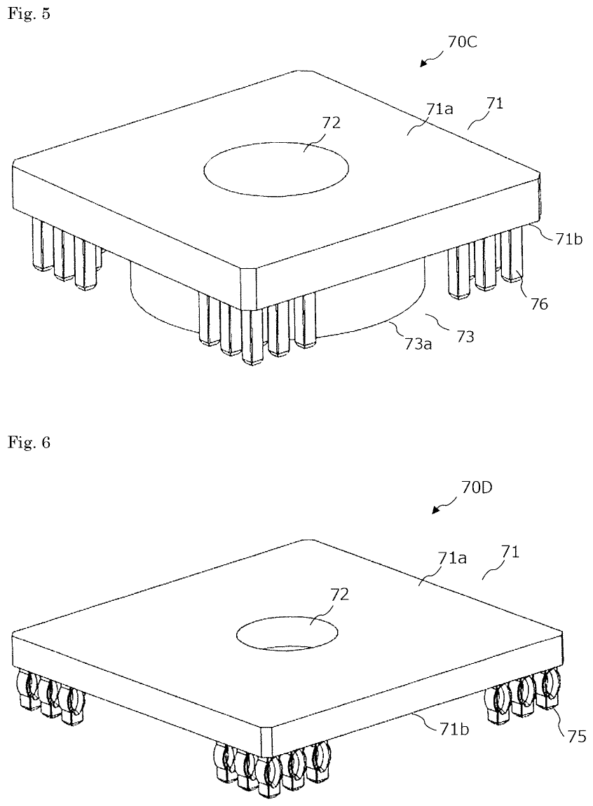

FIG. 5 illustrates a third configuration example of a busbar terminal block. A busbar terminal block 70C is different from the example of FIG. 3 in that it includes a plurality of metal DIP pins 76 instead of press-fit pins, but the other configuration is the same as that of the example of FIG. 3. The busbar terminal block 70C allows the board contact surface 71b of the plate portion 71 to be fixed to the board 6 by soldering the DIP pins 76 to the board 6. In that state, the second support surface 73a of the post portion 73 projects from the opposite surface of the board 6.

FIG. 6 illustrates a modification example of a busbar terminal block. A busbar terminal block 70D is different from the example of FIG. 3 in that it does not include a post portion.

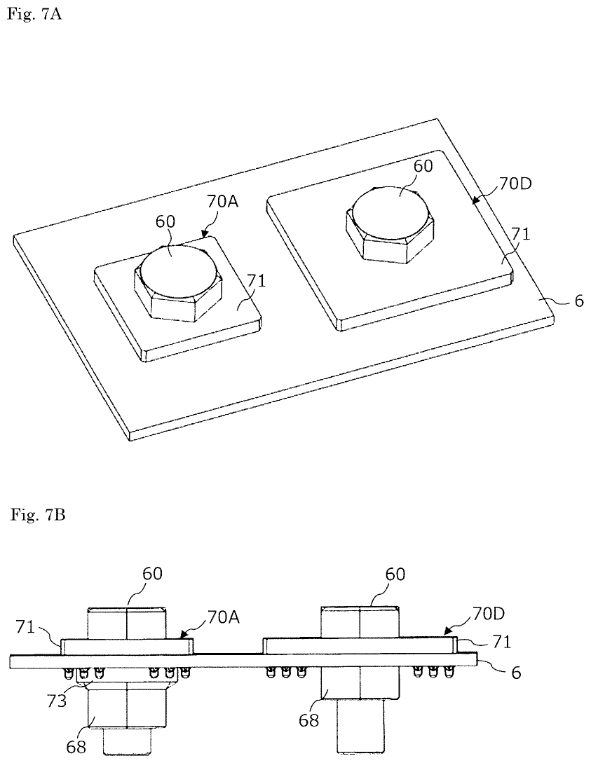

Referring to FIGS. 7A and 7B, a comparison is made between the busbar terminal block 70A (FIG. 3) and the busbar terminal block 70D (FIG. 6) fastened to the circuit board 6 with bolts 60 and nuts 68.

As can be seen from FIG. 7B, the busbar terminal block 70A is mounted to the board 6 with the press-fit pins passed through the circuit board 6 from the upper side. In this state, the post portion 73 projects from the lower surface of the board 6. The nut 68 contacts the post portion 73 from below. By contrast, the busbar terminal block 70D includes no post portion projecting from the lower surface of the circuit board 6.

Both the busbar terminal block 70A and the busbar terminal block 70D can be disposed so as to sandwich a busbar between the head of the bolt 60 and the plate portion 71 of the busbar terminal block. When the busbar disposed in that way is fastened and fixed, the busbar terminal block 70A can prevent the circuit board 6 from being partially crushed by the head of the bolt 60 and the nut 68 since the nut 68 contacts the post portion 73. On the other hand, the busbar terminal block 70D partially crushes the circuit board 6 with the head of the bolt 60 and the nut 68 since the nut 68 contacts the board 6.

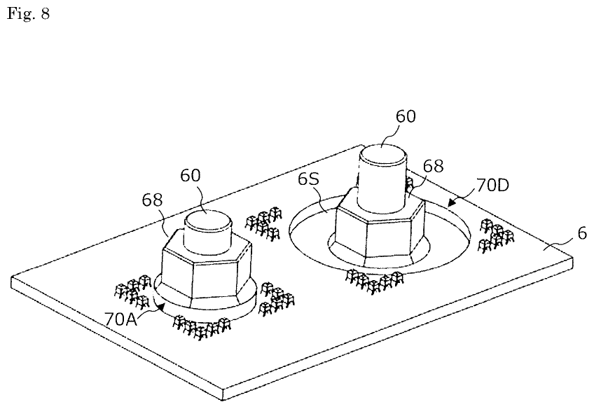

In order to prevent the circuit board 6 from being crushed while using the busbar terminal block 70D, it is necessary to provide, as illustrated in FIG. 8, a clearance space 6S in the board 6 to avoid interference with the nut 68. In the case of using the busbar terminal block 70A, such a clearance space is not necessary. It is sufficient that a hole through which the post portion 73 passes be formed in the board 6.

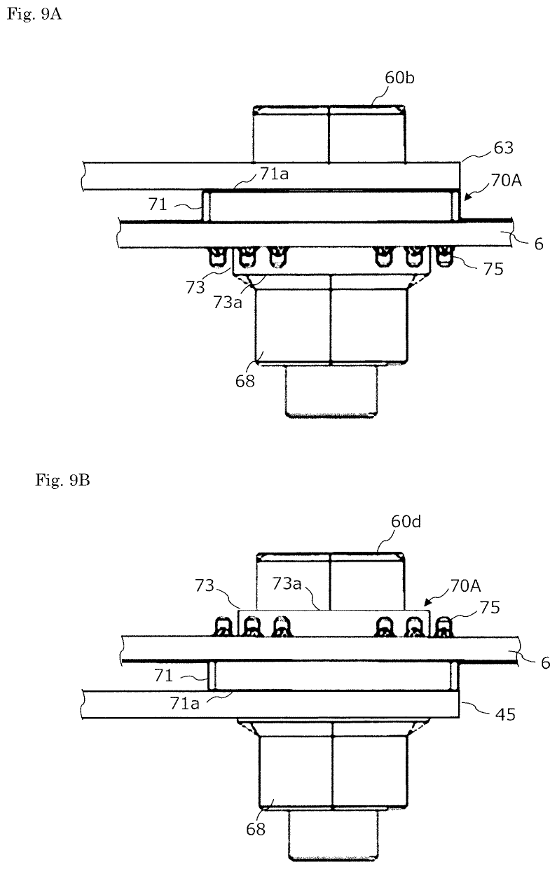

FIG. 9A illustrates the busbar 63 (see FIG. 2) fixed to the upper side of the board 6 using the busbar terminal block 70A. First, the busbar terminal block 70A is mounted from the upper side of the board 6. Next, the busbar 63 is placed on the first support surface 71a of the busbar terminal block 70A. Next, the bolt 60b is inserted from the upper side into a hole formed in the busbar 63 and the insertion hole 72 in the busbar terminal block 70A. The insertion hole 72 is not threaded, and the bolt 60b can be smoothly inserted. Finally, the nut 68 is fastened to the lower end of the bolt 60b. The nut 68 abuts on the second support surface 73a of the busbar terminal block 70A, thereby fixing the busbar 63 between the head of the bolt 60b and the busbar terminal block 70A (first support surface 71a).

FIG. 9B illustrates the busbar 45 (see FIG. 11) fixed to the lower side of the board 6 using the busbar terminal block 70A. First, the busbar terminal block 70A is mounted from the lower side of the board 6. Next, the busbar 45 is brought into contact with the first support surface 71a of the busbar terminal block 70A from below. Next, the bolt 60d is inserted from the upper side into the insertion hole 72 in the busbar terminal block 70A and a hole formed in the busbar 45. Finally, the nut 68 is fastened to the lower end of the bolt 60d. The nut 68 abuts on the lower surface of the busbar 45, thereby fixing the busbar 45 between the busbar terminal block 70A (first support surface 71a) and the nut 68.

In either case of FIGS. 9A and 9B, the busbar terminal block 70A is fixed to the board 6 with the press-fit pins 75, and the board 6 is not crushed even when the bolt 60 and the nut 68 are tightened with high torque. Consequently, a creep phenomenon in the circuit board 6 and the resulting bolt loosening can be prevented.

The press-fit pins 75 do not project beyond the second support surface 73a, and thus the press-fit pins 75 do not interfere with the nut 68 or the head of the bolt 60.

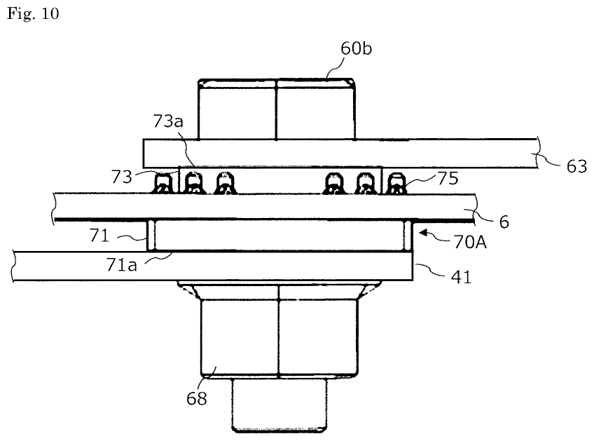

As illustrated in FIG. 10, it is also possible to fix the busbar 63 (see FIG. 2) to the upper side of the board 6 and fix the busbar 41 (see FIG. 11) to the lower side of the board 6, using the busbar terminal block 70A. First, the busbar terminal block 70A is mounted from the lower side of the board 6. Next, the busbar 63 is placed on the second support surface 73a of the busbar terminal block 70A. Next, the busbar 41 is brought into contact with the first support surface 71a of the busbar terminal block 70A from below. Next, the bolt 60b is inserted from the upper side into the hole formed in the busbar 63, the insertion hole 72 in the busbar terminal block 70A, and a hole formed in the busbar 41. Finally, the nut 68 is fastened to the lower end of the bolt 60d. The nut 68 abuts on the lower surface of the busbar 41, thereby fixing the busbar 63 between the head of the bolt 60b and the busbar terminal block 70A (second support surface 73a), and fixing the busbar 41 between the busbar terminal block 70A (first support surface 71a) and the nut 68.

The following summarizes an example embodiment of the present invention.

(1) The busbar terminal blocks 70A, 70B, and 70C include a conductive material and the plate portion 71 including the board contact surface 71b, the board contact surface 71b coming into contact (preferably surface contact) with the first surface of the circuit board 6, and the post portion 73 that extends from the plate portion 71 through the circuit board 6 and projects from the second surface of the circuit board 6. The plate portion 71 includes the first support surface 71a opposite the board contact surface 71b. The post portion 73 includes the second support surface 73a at the distal end that projects from the second surface. The plate portion 71 and the post portion 73 include the insertion hole 72 through which the fastener 60 is inserted, the insertion hole 72 linearly extending from the first support surface 71a to the second support surface 73a.

The above configuration can provide a busbar terminal block for fixing a busbar to the circuit board 6. The busbar terminal block with the first support surface and the second support surface allows a busbar to be fixed to either the upper side or the lower side of the board with high reliability. The busbar terminal block can be suitably applied to a circuit board such as a battery management unit in which busbars are fixed to the upper side and the lower side of the board.

(2) In the busbar terminal block of (1), the press-fit pins 75 may project from the board contact surface 71b.

The above configuration allows the board contact surface 71b of the plate portion 71 to be firmly fixed to the board 6 with high durability. The conductive busbar terminal block 70A can be fixed to the wiring on the board 6 with low contact resistance.

(3) In the busbar terminal block of (2), the press-fit pins 75 may have a height lower than the height from the board contact surface 71b to the second support surface 73a of the post portion 73.

The above configuration can prevent the press-fit pins 75 from interfering with the nut 68 or the head of the bolt 60.

(4) A management unit includes the circuit board 6, the shunt resistor 53 or 63 fixed to the circuit board 6, the busbar terminal block according to any one of (1) to (3) fixed to the circuit board 6, and a busbar fixed to the board via the busbar terminal block and electrically connected to the shunt resistor 53 or 63.

By adopting the new-concept busbar terminal block, the management unit of the above configuration is improved in the degree of freedom in design and the degree of freedom in cost. A busbar can be firmly fixed to either the upper side or the lower side of the board, using the busbar terminal block.

(5) In the management unit of (4), the shunt resistor 53 may be a surface-mount resistor (SMD type).

By adopting the SMD-type shunt resistor 53, the management unit of the above configuration can achieve significant cost reduction and miniaturization (or higher energy density). Even when mounted in a mobile object and exposed to vibration, the management unit can achieve high durability and reliability.

(6) An energy storage apparatus includes an energy storage device and the management unit according to (4) or (5).

The energy storage apparatus of the above configuration can monitor the current in the energy storage device with high accuracy, using the management unit, and can improve the accuracy of the estimation of the state of charge (SOC) by current integration and the estimation of other states of the energy storage device and the energy storage apparatus.

The present invention is not limited to the above-described example embodiments and can be modified as appropriate.

FIG. 9A illustrates an example in which the busbar 63 is fixed between the head of the bolt 60b and the busbar terminal block 70A. As an alternative proposition, the busbars 63 and 64 may be fixed between the head of the bolt 60c illustrated in FIG. 2 and the busbar terminal block.

Instead of a busbar, a shunt resistor with integrally-formed plate portions may be fixed to the board with the busbar terminal block.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A busbar terminal block comprising:
a conductive material;
a plate portion including a board contact surface contactable with a first surface of a circuit board; and
a post portion that extends from the plate portion through the circuit board and projects from a second surface of the circuit board; wherein
the plate portion includes a first support surface opposite the board contact surface;
the post portion includes a second support surface at a distal end that projects from the second surface; and
the plate portion and the post portion include an insertion hole through which a fastener is inserted, the insertion hole linearly extending from the first support surface to the second support surface.

2. The busbar terminal block according to claim 1, wherein a press-fit pin projects from the board contact surface.

3. The busbar terminal block according to claim 2, wherein the press-fit pin has a height lower than a height from the board contact surface to the second support surface of the post portion.

4. A management unit comprising:
a circuit board;
a shunt resistor fixed to the circuit board;
the busbar terminal block according to claim 1 fixed to the circuit board; and
a busbar fixed to the circuit board via the busbar terminal block and electrically connected to the shunt resistor.

5. The management unit according to claim 4, wherein the shunt resistor is a surface-mount resistor.

6. An energy storage apparatus comprising:
an energy storage device; and
the management unit according to claim 4.
